(19) United States
(12) Patent Application Publication
(10) Pub. No.: US 2026/0220345 A1
(43) Pub. Date: Jul. 30, 2026

(54) Integrated Circuit Design with Logic Cells Associated with Dependent Operating Elements Arranged in a Widening Structure

(71) Applicant: Google LLC, Mountain View, CA (US)

(72) Inventors: Pankaj Mudgil, Rohtak (IN); Neil Malhotra, Delhi (IN); Prajwal Subhash Barapatre, Bangalore (IN)

(73) Assignee: Google LLC, Mountain View, CA (US)

(21) Appl. No.: 19/039,179

(22) Filed: Jan. 28, 2025

Related U.S. Application Data
(60) Provisional application No. 63/750,159, filed on Jan. 27, 2025.

(51) Int. Cl. G06F 30/392; G06F 30/396; G06F 30/398

(52) U.S. Cl. CPC G06F 30/392; G06F 30/396; G06F 30/398

(57) ABSTRACT

This document describes systems and techniques for designing an integrated circuit with logic cells associated with dependent operating elements arranged in a widening structure. For example, a method includes associating logic cells into a plurality of groups associated with one of a plurality of dependent operating elements that each depend on a base operating element. The plurality of dependent operating elements are arranged in a widening structure at which the base operating element is at a proximal end of the widening structure and one or more levels of dependent operating elements are hierarchically arranged from the base operating element at the proximal end to a distal level of one or more operating elements at a distal end. Each of the plurality of groups of logic cells are clustered around each of the plurality of dependent operating elements with which the logic cells are associated.

### CROSS-REFERENCE TO RELATED APPLICATION(S)

This application claims the benefit of U.S. Provisional Patent Application Ser. No. 63/750,159 filed on Jan. 27, 2025, the disclosure of which is incorporated by reference herein in its entirety.

### SUMMARY

This document describes systems and techniques for designing an integrated circuit with logic cells associated with dependent operating elements arranged in a widening structure to enhance performance, reduce latency, conserve power, and make efficient use of available area.

For example, a method includes associating logic cells in a processing system into a plurality of groups, where the logic cells in each of the plurality of groups are associated with one of a plurality of dependent operating elements that each depend on a base operating element. The plurality of dependent operating elements are arranged in a widening structure at which the base operating element is at a proximal end of the widening structure and one or more levels of dependent operating elements are hierarchically arranged from the base operating element at the proximal end to distal level of one or more operating elements at a distal end of the widening structure. Each of the plurality of groups of logic cells are clustered around each of the plurality of dependent operating elements with which the logic cells in each of the plurality of groups is associated.

This Summary is provided to introduce systems and techniques for designing an integrated circuit with logic cells associated with dependent operating elements arranged in a widening structure, as further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques for designing an integrated circuit with logic cells associated with dependent operating elements arranged in a widening structure are described in this document with reference to the following Drawings. The same numbers are used throughout the drawings to reference like features and components.

FIG. 1 is a schematic diagram contrasting a conventional arrangement of logic cells to logic cells with dependent operating elements arranged in a widening structure;

FIG. 2 is a schematic diagram of a widening structure including a base operating element and a plurality of dependent operating elements;

FIG. 3 is a schematic diagram of a timing system for an integrated circuit including a general-purpose clock manager and a network of clock dividers as an example of the base operating element and the plurality of dependent operating elements of FIG. 2;

FIG. 4 is a schematic diagram of a distribution of logic elements operating at different clock speeds grouped into clusters around clock dividers of the appropriate clock speeds;

FIG. 5 is a schematic diagram of an optimized cluster including a group of logic elements clustered around a clock divider;

FIG. 6 is a schematic diagram of a linear widening structure of logic cells;

FIG. 7 is a schematic diagram of a nonlinear widening structure of logic cells;

FIG. 8 is a schematic diagram for determining dimensions of a nonlinear widening structure of logic elements; and

FIG. 9 is a flow diagram of an example method of designing an integrated circuit with logic cells associated with dependent operating elements arranged in a widening structure.

### DETAILED DESCRIPTION

### Overview

Integrated circuits, such as multicore processors and system-on-chip (SoC) devices, are highly complex systems including billions of separate devices that make up logic cells configured to perform processing, data storage, and other functions. As these devices become both increasingly more powerful and more compact, there is constant tension to make efficient use of the area available on a planar structure while separating devices and signal lines to prevent crosstalk, electromagnetic interference, voltage drops, and other concerns that may result if devices are formed too closely together.

Such devices typically rely on a base operating element, such as a general-purpose clock manager, that underscores operation of the entire device. The general-purpose clock manager may directly clock some processing operations while there are multiple levels of clock dividers arranged around the device to provide clock signals to clock other devices that operate at lower clock rates. A clock signal from the general-purpose clock manager is provided to multiple levels of clock dividers that, in parallel and/or successively, divide the clock signals into slower clock signals that clock other devices. A challenge to device designers is how to efficiently arrange the logic cells that make use of the clock signals generated by each of these clock dividers. Removing devices in a logic cell too far from a source of its clock signal may result in latency, as well as wasting some of the limited space that may be available on a device. On the other hand, positioning different devices and signal lines too closely together may result in cross-talk, undesirable electromagnetic interference, and other problems.

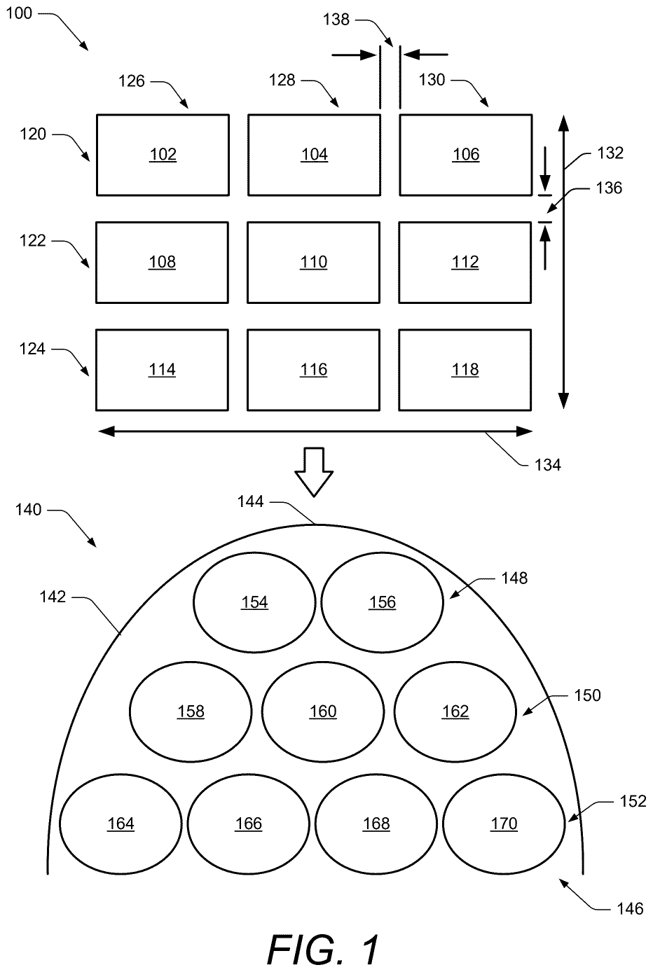

Conventional tools for device design, such as place and routing (PnR) tools tend to arrange logic cells in global routing cells (GCells), which are generally rectangular areas commonly used for planning and estimating the routing of electrical connections between logic cells, and scattered placement based on timing rectangular areas but this approach may not be the most efficient approach to designing a device because such a layout may result in having to include buffers in the design to create a workable clock system. FIG. 1 includes a conventionally-arranged device 100 that includes a number of generally rectangular GCells 102, 104, 106, 108, 110, 112, 114, 116, and 118 that, in turn, are arranged in a rectangular pattern of rows 120, 122, and 124 and columns 126, 128, and 130. It may be desirable to make the GCells 102, 104, 106, 108, 110, 112, 114, 116, and 118 as compact as possible and to compress the rows 120, 122, and 124 and columns 126, 128, and 130 as closely together as possible. Compressing the aspects of the device 100 as closely together as possible may reduce dimensions 134 and 136 to save space and to reduce latency by reducing the length of signal lines that may run across the dimensions 134 and/or 136. However, as previously described, it may be necessary to include spaces between the rows 120, 122, and 124, such as space 132, or between the columns 126, 128, and 130, such as space 138, to prevent against crosstalk and other issues. Balancing the desire to reduce size while incorporating needed gaps creates a tension in optimizing design of the device 100. Further, considering the generally rectangular structure of the device 100, it will be appreciated that the rectangular design does not naturally incorporate any hierarchical structure, such as may be needed or desired to provide divided clock signals to each of the many logic cells.

By contrast, FIG. 1 also shows a device 140 arranged in a widening structure 142 from a proximal end 144, at which a general-purpose clock manager may be positioned, to a distal end 146. Within the widening structure 142, logic cells 154, 156, 158, 160, 162, 164, 166, 168, and 170 are arranged in levels 148, 150, and 152. The levels 148, 150, and 152 may include groups of logic cells. For example, level 148 includes logic cells 154 and 156; level 150 includes logic cells 158, 160, and 162; level 152 includes logic cells 164, 166, 168, and 170. The logic cells 158, 160, and 162 at the second level 150 may operate on data or other signals generated by one or more of the logic cells 154 and 156 at the first level 148. In turn, the logic cells 164, 166, 168, and 170 at the third level 152 may operate on data or signals generated by one or more of the logic cells 158, 160, and 162 at the second level 150. The hierarchy implied by the widening structure 142 facilitates efficient operation of logic cells 154, 156, 158, 160, 162, 164, 166, 168, and 170 that may depend on outputs of others of the logic cells 154, 156, 158, 160, 162, 164, 166, 168, and 170.

### Examples of Widening Structures and Logic Cells

Integrated circuits, such as multicore processors and system-on-chip (SoC) devices, are highly complex systems including billions of separate devices that make up logic cells configured to perform processing, data storage, and other functions. As these devices become both increasingly more powerful and more compact, there is constant tension to make efficient use of the area available on a planar structure while separating devices and signal lines to prevent crosstalk, electromagnetic interference, voltage drops, and other concerns that may result if devices are formed too closely together.

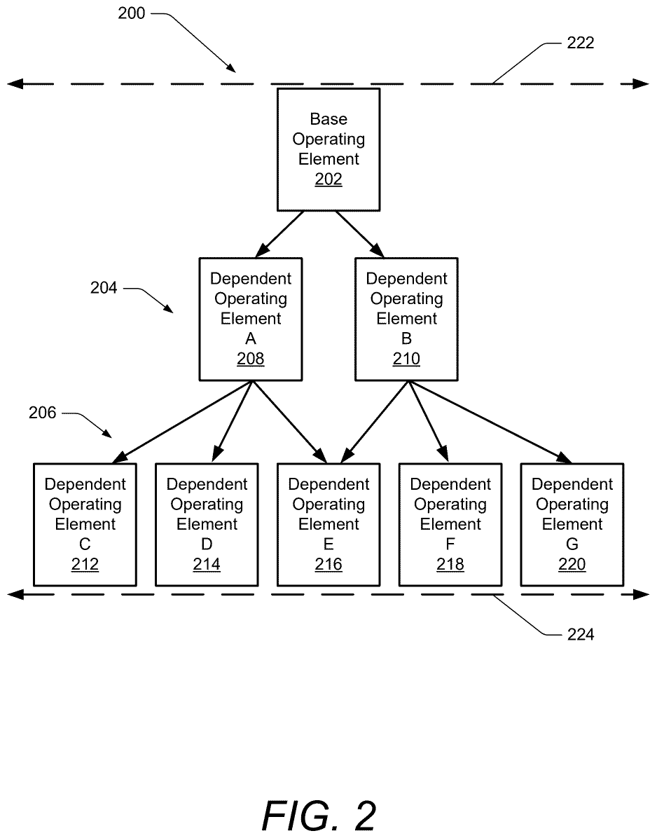

FIG. 2 shows a schematic diagram of a system 200 including a base operating element 202 and a plurality of dependent operating elements. The system 200 includes a hierarchy of levels 204 and 206 of dependent operating elements 208, 210, 212, 214, 216, 218, and 220 that depend on signals and/or data generated by the base operating element 202 and/or one or more of the dependent operating elements 208 and 210. For example, dependent operating element A 208 and dependent operating element B 210 on a second level 204 depend on signals and/or data generated by the base operating element 202. In turn, dependent operating element C 212, and dependent operating element D 214 on a third level 206 depend on signals and/or data generated by dependent operating element A 208. Similarly, dependent operating element F 218, and dependent operating element G 220 on the third level 206 depend on signals and/or data generated by dependent operating element B 210. Dependent operating element E 216 on the third level 206 depends on signals and/or data generated by both dependent operating element A 208 and dependent operating element B 210. This is a natural progression in most processing systems where multiple dependent operating elements depend on signals and/or data generated by one or more other operating elements to manipulate data, perform calculations, or another task, extending from the base operating element 202 at a proximal end 222 of the system 200 to a distal level (e.g., the third level 206 in the system 200) at a distal end 224 of the system 200. Logically hierarchical data structures originating from some element such as the base operating element 202 are natural in processing systems; however, a rectangularly-based implementation as in the system 100 (see FIG. 1) does not conform to this type of common processing hierarchy shown in the system 200 of FIG. 2.

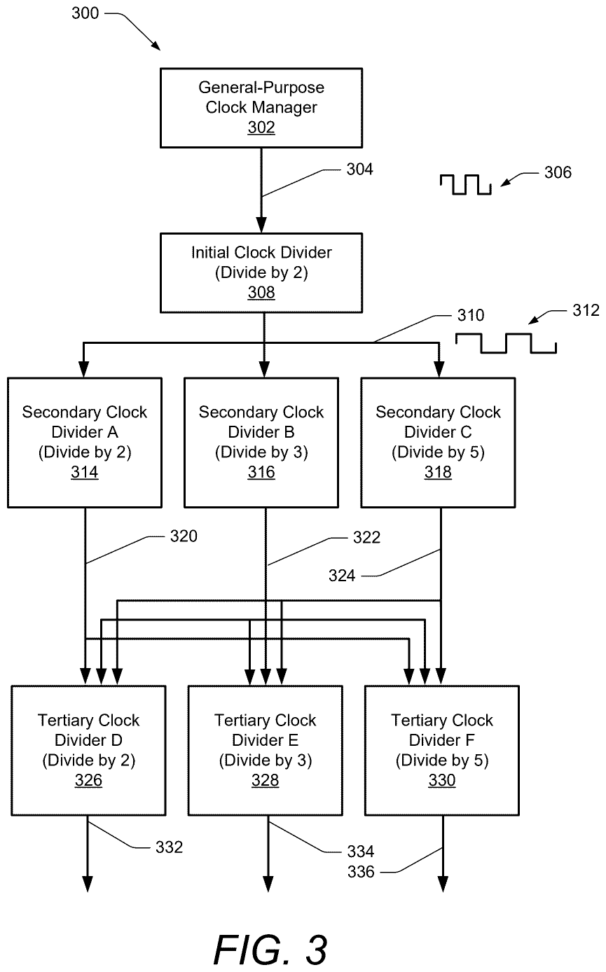

For example, as shown in FIG. 3, a timing structure 300 that may be used in many processing systems incorporates a natural hierarchy in providing clock signals for various aspects of a processing system. As described with reference to the system 200 (see FIG. 2), a processing system may include a plurality of dependent operating elements that depend on signals and/or data generated by other elements. As a result, some of the dependent elements operate at slower clock speeds to allow for the signals and/or data generated by the other elements to be generated and/or received by the dependent elements.

The timing structure 300 includes a general-purpose clock manager 302 which may include a phase-locked loop or other structure that provides a base system clock that provides a clock output 304 that includes a highest-speed clock signal 306. The clock output 304 is provided to one or more clock dividers to generate one or more lower speed clock signals that may be used to clock dependent operating elements that operate using signals and/or data generated by other operating elements as described with reference to FIG. 2. Lower-speed clock signals are needed by the dependent operating elements to allow for the signals and/or data that provide their inputs to be generated and communicated to the dependent operating elements. Operating the dependent operating elements at lower-speed clock signals allows for the generation and propagation of these signals.

In the example of FIG. 3, the clock output 304 providing the highest-speed clock signal 306 is provided to an initial clock divider 308 which may include a flip-flop or other device that is configured to divide the highest-speed clock signal 306 by two, thereby generating a second clock output 310 that presents a half-speed clock signal 312. One or more dependent operating elements (not shown in FIG. 3) may use the half-speed clock signal 306 to clock their operations to allow time for generation and receipt of signals and/or data from other operating elements.

As will be appreciated by those ordinarily skilled in the art, clock signals, such as the half-speed clock signal 312 may be further divided (e.g., usually by other prime number factors) to generate a succession of slower clock signals that may be used to clock other dependent operating elements. For example, the second clock output 310 carrying the half-speed clock signal 312 may be provided to a number of secondary clock dividers, such as secondary clock divider A 314 that further divides the half-speed clock signal 312 by two, secondary clock divider B 316 that further divides the half-speed clock signal 312 by three, and secondary clock divider C 318 that further divides the half-speed clock signal 312 by five. Furthermore, clock outputs 320, 322, and 324 of the secondary clock dividers 314, 316, and 318, respectively, may be provided to additional clock dividers 326, such as tertiary clock divider D 326 that is configured to further divide a received clock signal by two, tertiary clock divider E 326 that is configured to further divide a received clock signal by three, and tertiary clock divider F 330 that is configured to further divide a received clock signal by five to yield additional lower-speed clock outputs 332, 334, and 336 respectively.

The clock outputs 304, 310, 320, 322, 332, 334, and 336 may each provide clock signals to one or more dependent operating elements or other devices (not shown in FIG. 3) in a processing system. Because a group of devices may depend on a particular one of the clock dividers 308, 314, 316, 318, 326, 328, and 330, that group of devices may be physically clustered around the respective one of the clock dividers 308, 314, 316, 318, 326, 328, and 330 to form a logic cell of which the respective one of the clock dividers 308, 314, 316, 318, 326, 328, and 330 is a centroid of the logic cell. Clustering the devices in this way may reduce a distance that a divided clock signal line must run, thereby reducing possible latency.

Moreover, localizing the divided clock signal to the group of devices using a particular divided clock signal reduces crosstalk, interference, or other issues that may result from running multiple clock signal lines across or around a processing device. Further, placing the clock dividers close together and then routing the various clock signals throughout a computing device results in a hot spot at a location where the clock dividers are placed that may create both a heat dissipation problem and strain a power distribution system because of voltage drops at the region where the clock dividers are collected. Clustering logic elements around a clock divider on which each depends reduces problems with cross talk and interference, heat dissipation, and voltage drops.

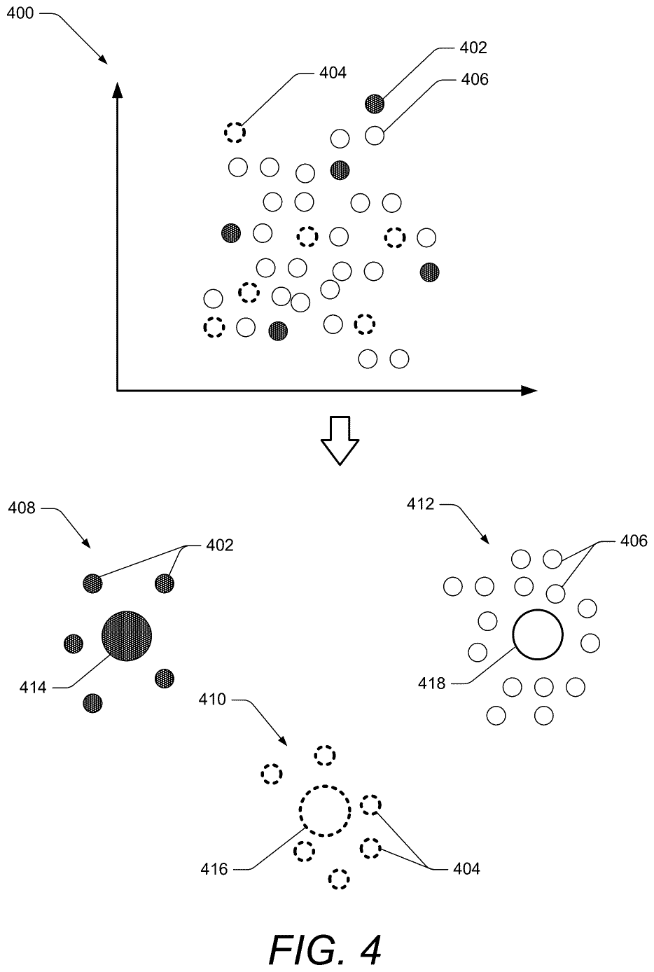

FIG. 4 is a schematic diagram of a distribution 400 of different types of logic elements 402, 404, and 406 operating at different clock speeds. The distribution 400 is a collection of data points where the data points represent each of the logic elements in a design of a processing device. The logic elements 402, 404, and 406 are characterized according to clock speed, as represented by the different shading of the different types of logic elements 402, 404, and 406. The logic elements 402, 404, and 406 are then grouped into clusters 408, 410, and 412 according to clock speed with centroids 414, 416, and 418 of each of the clusters 408, 410, and 412, respectively, being clock dividers of the appropriate clock speeds. (The centroids 414, 416, and 418 are represented in FIG. 4 as enlarged circles having the same shading as the logic elements 402, 404, and 406 that operate at the speed of the clock dividers represented by the centroids 414, 416, and 418.) As needed or desired, there may be multiple clusters operating at a same clock, although only one cluster operating at each clock speed is shown in FIG. 4. Once the logic elements 402, 404, and 406 are grouped into clusters 408, 410, and 412, respectively, the clusters 408, 410, and 412 may be optimized to efficiently use space.

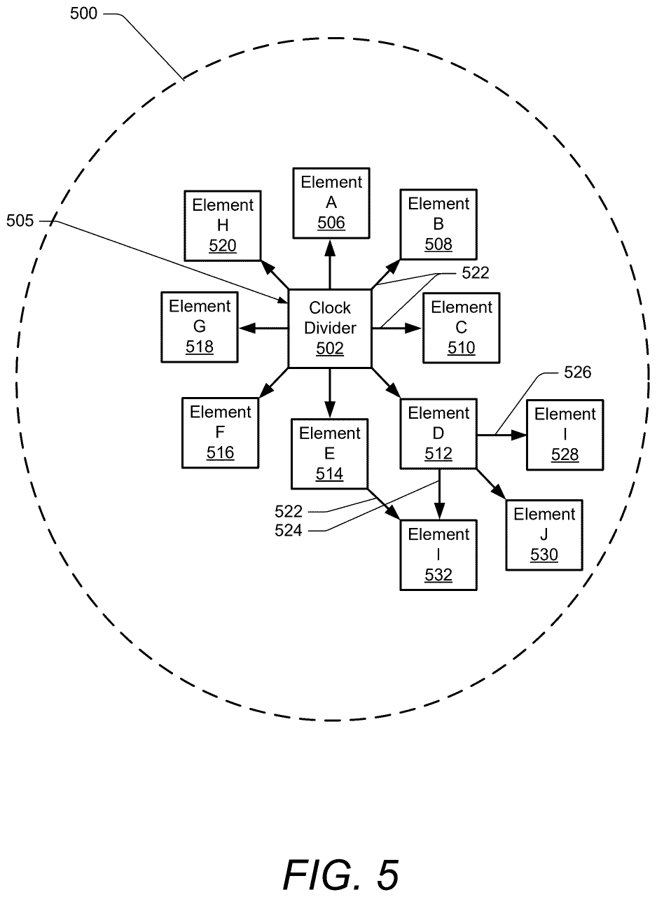

FIG. 5 shows a sample logic cell 500 that is clustered around a clock divider 502 that receives a clock signal or divided clock signal from another device (not shown in FIG. 5). In aspects, the clock divider 502 is a centroid 504 of the logic cell 500 because the clock divider 502 is coupled directly to at least a first set of elements 506, 508, 510, 512, 514, 516, 516, 518, and 520 that depend on a clock output 522 of the clock divider 502. Because the operation of the elements 506, 508, 510, 512, 514, 516, 518, and 520 is clocked by the clock output 522 of the clock divider 502, clustering the elements 506, 508, 510, 512, 514, 516, 518, and 520 around the clock divider 502 may be used to reduce lengths of signal lines carrying the clock output 522 to the elements 506, 508, 510, 512, 514, 516, 518, and 520, which may reduce latency in the communication of a signal carried by the clock output 522 to the elements 506, 508, 510, 512, 514, 516, 518, and 520. In addition, by localizing the clock output 522 to the elements 506, 508, 510, 512, 514, 516, 518, and 520, risk of crosstalk or other interference with other clock outputs or signals is reduced. Floor-planning may be used to achieve optimal spatial integration, as can be appreciated by the contrast of the original clustering depicted in FIG. 4 with the more efficient layout of logic elements shown in FIG. 5. An iterative process may be used to achieve efficient spatial integration.

Similarly, additional elements which rely on outputs 522, 524, and 526 of one or more of the elements 506, 508, 510, 512, 514, 516, 518, and 520, such as additional elements 528, 530, and/or 532, may be clustered around the elements 506, 508, 510, 512, 514, 516, 518, and 520. This clustering of elements 506, 508, 510, 512, 514, 516, 518, 520, 528, 530, and 532 around the clock divider 502 and/or other elements makes efficient use of space and reduces length of signal lines used to carry clock signals and other signals between the elements in the logic cell 500. The logic cell 500 is depicted as an ellipse to contain the elements 506, 508, 510, 512, 514, 516, 518, 520, 528, 530, 532, and additional elements (not shown) of the logic cell 500. However, it should be appreciated that the elliptical shape of the logic cell 500 is representative of clustering or arranging the logic cells close to the elements from which they depend. No rounded or regular shape is required to condense the logic cell 500 to benefit from the reduced signal lines between a particular element and additional elements on which those additional elements depend for signals and/or data.

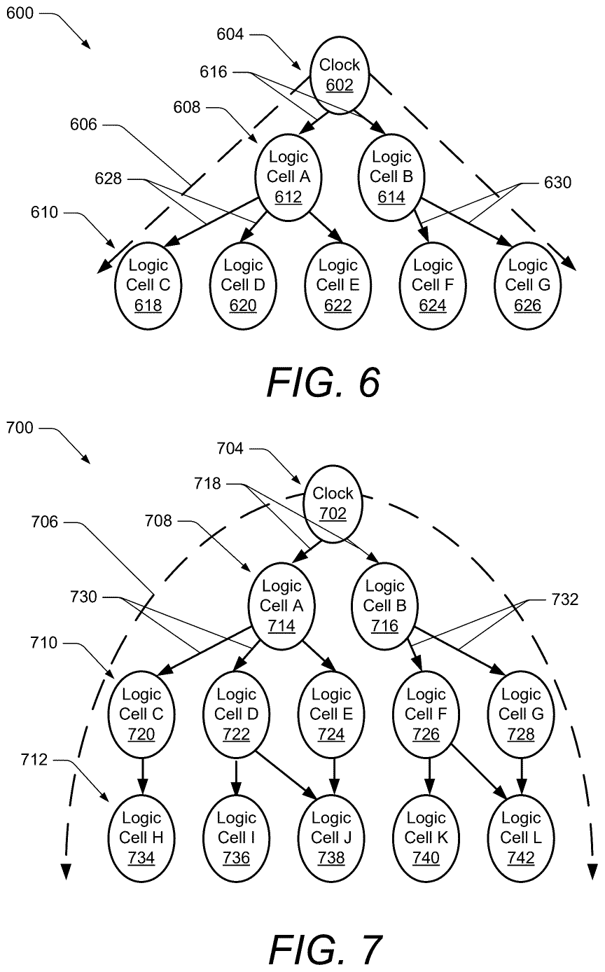

Referring to FIGS. 6 and 7, it can be seen that combining a hierarchy naturally implied by a clock structure or other dependency of elements, logic cells clustered around clock dividers or other operating element may be collected in a widening structure of logic cells extending from a base operating element such as a general-purpose clock manager. The example of a general-purpose clock manager (“clock” in FIGS. 6 and 7) is used in the examples of both FIGS. 6 and 7 as a base operating element at a vertex of the widening structure.

FIG. 6 is a schematic diagram of a system 600 including a clock 602 at a vertex 604 of a widening structure 606. Proceeding from the clock 602 at the vertex 604, the schematic diagram of the system 600 also shows two additional levels including a first level 608 and a second level 610. The first level 608 includes logic cell A 612 and logic cell B 614 that receive a clock signal 616 from the clock 602. As described with reference to FIG. 4, each of the logic cells 612 and 614 in the first level 608 may include a clock divider and other logic elements clustered around the clock divider (not shown in FIG. 4) and are represented by ellipses as described with reference to FIG. 4. A second level 610 may include logic cell C 618, logic cell D 620, logic cell E 622, logic cell F 624, and logic cell G 626. Logic cell C 618, logic cell D 620, and logic cell E 622 may, for example, rely on divided clock signals 628 received from logic cell A 612 while logic cell F 624 and logic cell G 626 may rely on divided clock signals 630 from logic cell B 614. Logic cell C 618, logic cell D 620, logic cell E 622, logic cell F 624, and logic cell G 626 may each include another clock divider that further divides the respective divided clock signals 628 and 630 to clock logic elements included within the respective logic cells 618, 620, 622, 624, and 626.

As previously described, the logic cells 612, 614, 618, 620, 622, 624, and 626 each being clustered around a clock divider or other base operating element reduces the length of signal lines from that clock divider or base operating element to each of the other elements to reduce latency and avoid crosstalk or other interference with adjacent elements. Although signal lines may extend from some of the logic cells to others of the logic cells as described with referenced to the divided clock signal of logic cell A 612 to logic cell C 618, logic cell D 620, and logic cell E 622, these signal lines extend directly to the logic cells 618, 620, and 622 dependent on these signal lines that are placed adjacent to the logic cell 612 that is the source of those signal lines, reducing the distance the signal line extends. As a result, latency, interference, and other undesirable effects that may result from extended signal lines are avoided or reduced.

Depending on the number of levels of logic cells and the number of logic cells included within each of the levels, a widening structure may have a linear, triangular shape, as demonstrated in the widening structure 606 of FIG. 6 including linear boundaries 632 that circumscribe the system 400 of the clock 602 and the logic cells 612, 614, 618, 620, 622, 624, and 626.

However, the number of levels of logic cells and the number of logic cells included within each of the levels may suggest a different widening structure. For example, when the logic cells are clustered around clock dividers as described with reference to FIG. 4, logic cells within successive levels of logic cells in a widening structure may each include a clock divider. However, because clock dividers typically are configured to further divide a received clock signal by two, three, or five, the width of each of the levels may not be as large as a length of a number of descending levels of logic cells. Accordingly, the clusters of logic cells within the various levels may dictate a parabolic or semi-elliptical shape to bound a number of levels where the width does not increase or does not increase proportionally with a length of the widening structure.

FIG. 7 is a schematic diagram of a system 700 including a clock 702 at a vertex 704 of a non-linear widening structure 706. Proceeding from the clock 702 at the vertex 704, the schematic diagram of the system 700 shows three levels including a first level 708, a second level 710, and a third level 712. The first level 708 includes logic cell A 714 and logic cell B 716 that receive a clock signal 718 from the clock 702. A second level 710 may include logic cell C 720, logic cell D 722, logic cell E 724, logic cell F 726, and logic cell G 728, similar to the system 600 of FIG. 6. Logic cell C 720, logic cell D 722, and logic cell E 724 may, for example, rely on divided clock signals 730 received from logic cell A 714 while logic cell F 726 and logic cell G 728 may rely on divided clock signals 732 from logic cell B 716, also similar to system 500 of FIG. 5.

However, by contrast with the system 600 of FIG. 6, the system of FIG. 7 includes the third logic level 712 which includes logic cell H 734, logic cell I 736, logic cell J 738, logic cell K 740, and logic cell L 742. The number of the logic cells in the third row 712 is the same as the number of logic cells in the second level 710. As a result, instead of the system 500 with the linearly-widening structure 506 as described with reference to FIG. 5, the system 700 of FIG. 7 defines a parabolic or semi-elliptical shape 706 from the vertex. The system 700 offers the same type of benefits as the system 600 of FIG. 6 with logic cells clustered around clock dividers or other base operating elements, reducing a length of signal lines to reduce latency, interference, and other undesirable effects that may result from extended signal lines are avoided or reduced. In the case of the system 700, the nonlinear widening structure 706 is tailored to the number and hierarchy of the logic cells 714, 716, 720, 722, 724, 726, 728, 734, 736, 738, 740, and 742. Thus, in contrast to the linear widening structure 506, which would describe a continually-widening footprint even if the number of logic cells in successive levels does not continue to increase, the nonlinear widening structure 706 makes more efficient use of space on the device.

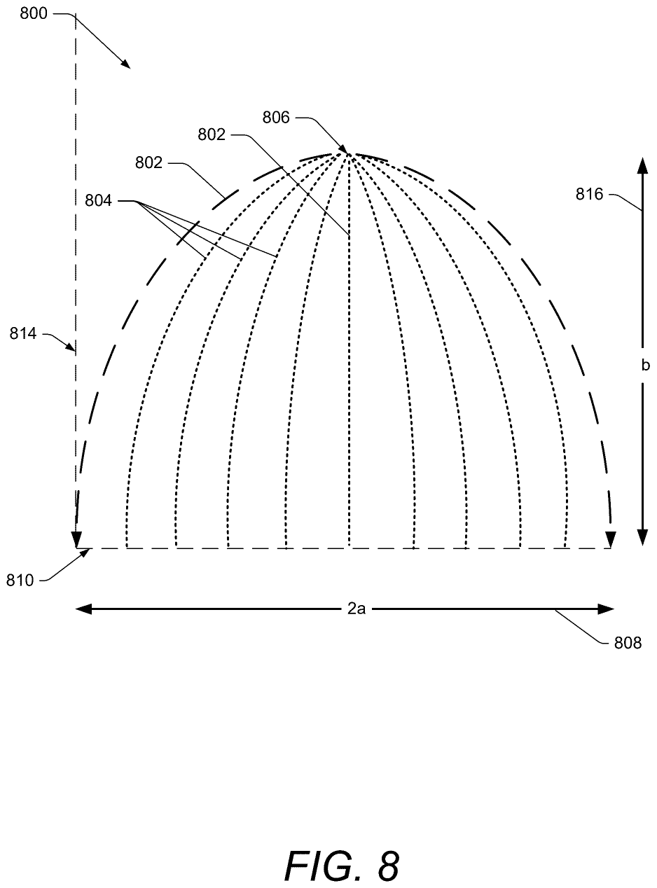

FIG. 8 depicts how a size of nonlinear widening structure 800 may be determined based on parameters of the logic cells. The nonlinear widening structure 800 is bounded by a parabola or semi-ellipse 802, as previously described, which encompasses signal lines 804 extending from a vertex 806 that, as previously described, may include a general-purpose clock manager. The nonlinear widening structure 800 has a width 2a 808 at an end 810 of the widening structure 800 (where a represents an eccentricity from a central axis 812 of the widening structure 800 to an edge 814 of the widening structure 800) and a length b 816 from the vertex 806 to the end 810 of the widening structure 800. A size y of the widening structure 800 may be determined from Eq. (1):

$$Area = π ( ab ) / 2 \qquad ( 1 )$$

The size of the nonlinear widening structure 800 and utilization of area is dependent on many factors that may be determined by design choices. Considering the cluster of FIG. 5 as an example of one of the clusters in the widening structure, where n is the number of logic elements, m is the average number of pins per logic element, f is the average fanout size of each of the logic elements, and p is an average wire length for each of the connections, the total area of the signal tracks may be determined from Eq. (2):

$$Signal track area = n * m * f * p \qquad ( 2 )$$

The size of the signal track area may be affected or adjusted by various considerations. For example, allowing for 20% of signal lines to be unusable because of crosstalk results in a first adjusted signal track area determined by Eq. (3) (in which only 0.8 of the signal lines are usable):

$$First adjusted signal track area = ( n * m * f * p ) / 0.8 \qquad ( 3 )$$

A second adjusted track area may consider a number of layers u that are used for differential routing. The second adjusted track area may be determined from Eq. (4):

$$Second adjusted signal track area = ( n * m * f * p ) / ( u * 0.8 ) \qquad ( 4 )$$

A third adjusted track area may allow for a percentage of non-default rules tracks that are incorporated in addition to the tracks created according to default rules. For purposes of example, it will be assumed that the design includes an additional 5% of non-default rules. The third adjusted signal track area may be determined from Eq. (5):

$$Third adjusted signal track area = 1.05 * ( n * m * f * p ) / ( u * 0.8 ) \qquad ( 5 )$$

A fourth adjusted track area includes an area consumed by added power and/or ground tracks g and may be determined from Eq. (6):

$$Fourth adjusted signal track area = 1.05 * ( n * m * f * p ) / ( u * 0.8 ) + g \qquad ( 6 )$$

Lastly, incorporating a routing pitch yields a fifth adjust signal track area that may be determined by Eq. (7):

$$Fifth adjusted signal track area = pitch ( 1.05 * ( n * m * f * p ) / ( u * 0.8 ) + g \qquad ( 7 )$$

Thus, the size of the signal track area between the logic cells may be determined by selecting design features. These choices ultimately contribute to a size of the widening structure 800 that includes the logic cells.

### Example Method of Forming a Widening Structure of Logic Cells

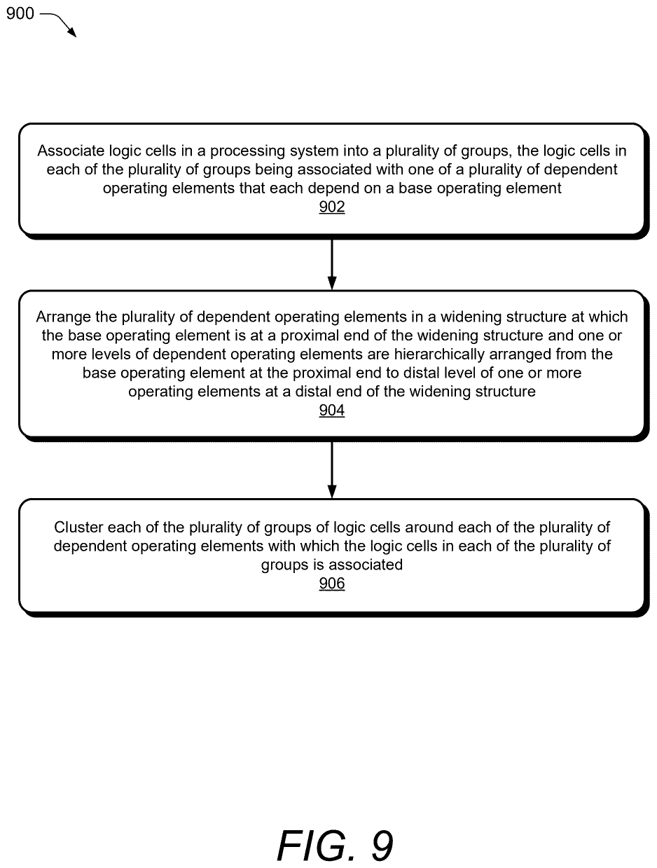

FIG. 9 shows a flow diagram of an example method 900 of a process of forming a widening structure of logic cells as previously described with reference to FIGS. 1-8. At a block 902, logic cells in a processing system are associated into a plurality of groups, the logic cells in each of the plurality of groups being associated with one of a plurality of dependent operating elements that each depend on a base operating element. At a block 904, the plurality of dependent operating elements are arranged in a widening structure at which the base operating element is at a proximal end of the widening structure and one or more levels of dependent operating elements are hierarchically arranged from the base operating element at the proximal end to distal level of one or more operating elements at a distal end of the widening structure. At a block 906, each of the plurality of groups of logic cells are clustered around each of the plurality of dependent operating elements with which the logic cells in each of the plurality of groups is associated. The organization of the logic cells and the structure of the overall widening structure, e.g., based on optimization of logic element placement, addition of power and ground lines and by changing the routing pitch, etc., as previously described, may be performed to achieve desired design objectives.

Unless context dictates otherwise, use herein of the word “or” may be considered use of an “inclusive or,” or a term that permits inclusion or application of one or more items that are linked by the word “or” (e.g., a phrase “A or B” may be interpreted as permitting just “A,” as permitting just “B,” or as permitting both “A” and “B”). Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying figures and terms discussed herein may be indicative of one or more items or terms, and thus reference may be made interchangeably to single or plural forms of the items and terms in this written description.

### CONCLUSION

Although implementations of systems and techniques for designing an integrated circuit with logic cells associated with dependent operating elements arranged in a widening structure have been described in language specific to certain features and/or methods, the subject of the appended claims is not necessarily limited to the specific features or methods described. Rather, the specific features and methods are disclosed as example implementations of systems and techniques for designing an integrated circuit with logic cells associated with dependent operating elements arranged in a widening structure.

1. A method comprising:
associating logic cells in a processing system into a plurality of groups, the logic cells in each of the plurality of groups being associated with one of a plurality of dependent operating elements that each depend on a base operating element;
arranging the plurality of dependent operating elements in a widening structure at which the base operating element is at a proximal end of the widening structure and one or more levels of dependent operating elements are hierarchically arranged from the base operating element at the proximal end to a distal level of one or more operating elements at a distal end of the widening structure; and
clustering each of the plurality of groups of logic cells around each of the plurality of dependent operating elements with which the logic cells in each of the plurality of groups is associated.

2. The method of claim 1, wherein the base operating element includes a general-purpose clock manager providing a clock signal at a clock speed and each of the dependent common operating elements includes a clock divider providing a dependent clock signal at a fraction of the clock speed.

3. The method of claim 2, wherein the one or more levels of the widening structure includes:
a first level including a first set of clock dividers that each receive the clock signal and divide the clock speed into a first set of clock signals at a first set of fractions of the clock speed; and
a second level including a second set of clock dividers that each receive one of the first set of clock signals and divide the clock speed into a second set of clock signals at a second set of fractions of the clock speed where the second fractions of the clock speed are slower than the first fractions of the clock speed.

4. The method of claim 1, wherein the widening structure extends from the proximal end in:
a conical array;
a parabolic array; or
a semi-elliptical array.

5. The method of claim 1, wherein the logic cells in each of the plurality of groups are arranged around an associated dependent common operating element.

6. The method of claim 5, wherein the logic cells in each of the plurality of groups are arranged concentrically around the associated dependent common operating element.

7. The method of claim 5, further comprising optimizing placement of the logic cells around the associated dependent common operating element to reduce space consumed by the logic cells.

8. (canceled)

9. (canceled)

10. One or more computer-readable storage media storing instructions that, responsive to execution by a processor, perform operations comprising:
associating logic cells in a processing system into a plurality of groups, the logic cells in each of the plurality of groups being associated with one of a plurality of dependent operating elements that each depend on a base operating element;
arranging the plurality of dependent operating elements in a widening structure at which the base operating element is at a proximal end of the widening structure and one or more levels of dependent operating elements are hierarchically arranged from the base operating element at the proximal end to a distal level of one or more operating elements at a distal end of the widening structure; and
clustering each of the plurality of groups of logic cells around each of the plurality of dependent operating elements with which the logic cells in each of the plurality of groups is associated.

11. The computer-readable storage media of claim 10, wherein the base operating element includes a general-purpose clock manager configured to generate a clock signal at a clock speed and one or more of the dependent operating elements include clock dividers configured to provide dependent clock signals at a fraction of the clock speed, further comprising instructions to route a clock signal generated by the general-purpose clock manager to the clock dividers.

12. The computer-readable media of claim 11, wherein the one or more levels of the widening structure includes:
a first level including a first set of clock dividers that each receive the clock signal and divide the clock speed into a first set of clock signals at a first set of fractions of the clock speed; and
a second level including a second set of clock dividers that each receive one of the first set of clock signals and divide the clock speed into a second set of clock signals at a second set of fractions of the clock speed where the second fractions of the clock speed are slower than the first fractions of the clock speed.

13. The computer-readable media of claim 10, wherein the widening structure extends from the proximal end in:
a conical array;
a parabolic array; or
a semi-elliptical array.

14. The computer-readable media of claim 10, wherein the logic cells in each of the plurality of groups are arranged around an associated dependent common operating element.

15. The computer-readable media of claim 14, wherein the logic cells in each of the plurality of groups are arranged concentrically around the associated dependent common operating element.

16. The computer-readable media of claim 14, further comprising optimizing placement of the logic cells around the associated dependent common operating element to reduce space consumed by the logic cells.

17. A system comprising:
a base operating element;
a plurality of dependent operating elements that each depend on the base operating element and are arranged in a widening structure with the base operating element at a proximal end of the widening structure and one or more levels of dependent operating elements hierarchically arranged from the base operating element at the proximal end to a distal level of one or more operating elements at a distal end of the widening structure; and
a plurality of groups of logic cells, each of the groups of logic cells including a plurality of logic cells being associated with one of the plurality of dependent operating elements and clustered around the associated dependent operating element.

18. The system of claim 17, wherein the base operating element includes a general-purpose clock manager providing a clock signal at a clock speed and each of the dependent common operating elements includes a clock divider providing a dependent clock signal at a fraction of the clock speed.

19. The system of claim 18, wherein the one or more levels of the widening structure includes:
a first level including a first set of clock dividers that each receive the clock signal and divide the clock speed into a first set of clock signals at a first set of fractions of the clock speed; and
a second level including a second set of clock dividers that each receive one of the first set of clock signals and divide the clock speed into a second set of clock signals at a second set of fractions of the clock speed where the second fractions of the clock speed are slower than the first fractions of the clock speed.

20. The system of claim 17, wherein the widening structure extends from the proximal end in:
a conical array;
a parabolic array; or
a semi-elliptical array.

21. The system of claim 17, wherein the logic cells in each of the plurality of groups are arranged around an associated dependent common operating element.

22. The system of claim 20, wherein the logic cells in each of the plurality of groups are arranged:
concentrically around the associated dependent common operating element; or
in an optimized pattern to reduce space consumed by the logic cells.
